(19) United States
(12) Patent Application Publication
(10) Pub. No.: US 2023/0402339 A1
(43) Pub. Date: Dec. 14, 2023

(54) Molding Structures for Integrated Circuit Packages and Methods of Forming the Same

(71) Applicant: Taiwan Semiconductor Manufacturing Co., Ltd., Hsinchu (TW)

(72) Inventors: Shu-Shen Yeh, Taoyuan City (TW); Chin-Hua Wang, New Taipei City (TW); Chipta Priya Laksana, Taoyuan City (TW); Po-Yao Lin, Zhudong Township (TW); Shin-Puu Jeng, Hsinchu (TW)

(21) Appl. No.: 17/840,362

(22) Filed: Jun. 14, 2022

(51) Int. Cl. H01L 23/31; H01L 23/538; H01L 23/16; H01L 23/00; H01L 21/48; H01L 21/56

(52) U.S. Cl. CPC H01L 23/3128; H01L 23/3135; H01L 23/5383; H01L 23/16; H01L 23/562; H01L 21/4853; H01L 21/4857; H01L 21/563; H01L 21/565

(57) ABSTRACT

In an embodiment, a method of forming a semiconductor device includes: attaching an integrated circuit die to an interposer; forming an encapsulant over the interposer and around the integrated circuit die, a top surface of the encapsulant and a top surface of the integrated circuit die being level; forming recesses in the encapsulant; and bonding the interposer to a package substrate, wherein after bonding the interposer to the package substrate, each of the recesses being along an outer edge of the encapsulant.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit die.

FIGS. 2-10D are views of intermediate stages in the manufacturing of integrated circuit packages, in accordance with some embodiments.

FIGS. 11A-13B are views of intermediate stages in the manufacturing of integrated circuit packages, in accordance with some embodiments.

FIGS. 14-20B are views of intermediate stages in the manufacturing of integrated circuit packages, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, integrated circuit packages are formed by packaging integrated circuit dies over a wafer. Encapsulant is formed over the wafer and around the integrated circuit dies. In some embodiments, recesses are etched in the encapsulant along scribe regions of the wafer. The wafer is singulated to form intermediate package components, which converts the recesses into recessed regions or indents (e.g., slant molding regions) in the encapsulant along outer edges of the encapsulant. The package components are then attached to package substrates to form the integrated circuit packages. In some embodiments, the encapsulant is etched to form the recessed regions after attaching the package components to the package substrate. Forming the recessed regions in the encapsulant advantageously provides control (e.g., reduction) of stress in the encapsulant during subsequent thermal processes, such as attachment of the package components to the package substrate, and/or thermal cycle testing of the integrated circuit package.

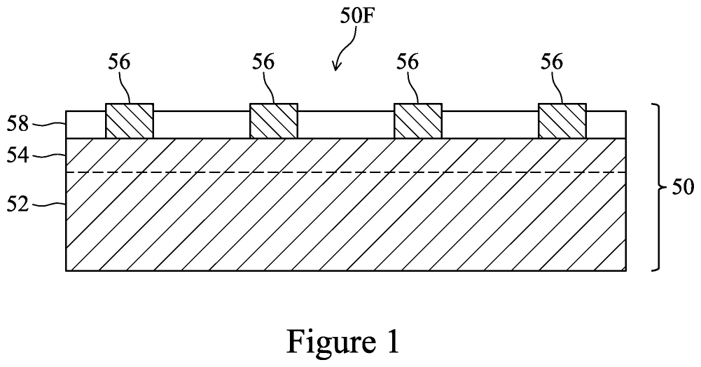

FIG. 1 is a cross-sectional view of an integrated circuit die 50. Integrated circuit dies 50 will be packaged in subsequent processing to form integrated circuit packages. Each integrated circuit die 50 may be a logic device (e.g., central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), the like, or a combination thereof (e.g., a system-on-a-chip (SoC) die). The integrated circuit die 50 may be formed in a wafer, which may include different die regions that are singulated in subsequent steps to form a plurality of integrated circuit dies 50. The integrated circuit die 50 includes a semiconductor substrate 52, an interconnect structure 54, die connectors 56, and a dielectric layer 58.

The semiconductor substrate 52 may be a substrate of silicon, doped or undoped, or an active layer of a semiconductor-on-insulator (SOI) substrate. The semiconductor substrate 52 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 52 has an active surface (e.g., the surface facing upward) and an inactive surface (e.g., the surface facing downward). Devices are at the active surface of the semiconductor substrate 52. The devices may be active devices (e.g., transistors, diodes, etc.), capacitors, resistors, etc. The inactive surface may be free from devices.

The interconnect structure 54 is over the active surface of the semiconductor substrate 52, and is used to electrically connect the devices of the semiconductor substrate 52 to form an integrated circuit. The interconnect structure 54 may include one or more dielectric layer(s) and respective metallization layer(s) in the dielectric layer(s). Acceptable dielectric materials for the dielectric layers include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The metallization layers may include conductive vias and/or conductive lines to interconnect the devices of the semiconductor substrate 52. The metallization layers may be formed of a conductive material, such as a metal, such as copper, cobalt, aluminum, gold, combinations thereof, or the like. The interconnect structure 54 may be formed by a damascene process, such as a single damascene process, a dual damascene process, or the like.

Die connectors 56 are at the front-side 50F of the integrated circuit die 50. The die connectors 56 may be conductive pillars, pads, or the like, to which external connections are made. The die connectors 56 are in and/or on the interconnect structure 54. For example, the die connectors 56 may be part of an upper metallization layer of the interconnect structure 54. The die connectors 56 can be formed of a metal, such as copper, aluminum, or the like, and can be formed by, for example, plating, or the like. In an embodiment the die connectors 58 may be microbumps, ball grid array (BGA) connectors, solder balls, metal pillars, controlled collapse chip connection (C4) bumps, electroless nickel-electroless palladium-immersion gold technique (ENEPIG) formed bumps, or the like. The die connectors 58 may include a conductive material such as solder, copper, aluminum, gold, nickel, silver, palladium, tin, the like, or a combination thereof. In some embodiments, the die connectors 58 are formed by initially forming a layer of solder through evaporation, electroplating, printing, solder transfer, ball placement, or the like. Once a layer of solder has been formed on the structure, a reflow may be performed in order to shape the material into the desired bump shapes.

Optionally, solder regions (not separately illustrated) may be disposed on the die connectors 56 during formation of the integrated circuit die 50. The solder regions may be used to perform chip probe testing on the integrated circuit die 50. For example, the solder regions may be solder balls, solder bumps, or the like, which are used to attach a chip probe to the die connectors 56. Chip probe testing may be performed on the integrated circuit die 50 to ascertain whether the integrated circuit die 50 is a known good die (KGD). Thus, only integrated circuit dies 50, which are KGDs, undergo subsequent processing are packaged, and dies which fail the chip probe testing are not packaged. After testing, the solder regions may be removed in subsequent processing steps.

A dielectric layer 58 is at the front-side 50F of the integrated circuit die 50. The dielectric layer 58 is in and/or on the interconnect structure 54. For example, the dielectric layer 58 may be an upper dielectric layer of the interconnect structure 54. The dielectric layer 58 laterally encapsulates the die connectors 56. The dielectric layer 58 may be an oxide, a nitride, a carbide, a polymer, the like, or a combination thereof. The dielectric layer 58 may be formed, for example, by spin coating, lamination, chemical vapor deposition (CVD), or the like. The dielectric layer 56 may be patterned to form openings, and the die connectors 58 may be formed in the openings. Portions of the die connectors 58 may be disposed over the dielectric layer 56 or protrude above the dielectric layer 56. In some embodiments, the dielectric layer 58 may bury the die connectors 56, such that the top surface of the dielectric layer 58 is above the top surfaces of the die connectors 56. The die connectors 56 are exposed through the dielectric layer 58 during formation of the integrated circuit die 50. Exposing the die connectors 56 may remove any solder regions that may be present on the die connectors 56. A removal process can be applied to the various layers to remove excess materials over the die connectors 56. The removal process may be a planarization process such as a chemical mechanical polish (CMP), an etch-back, combinations thereof, or the like. in some embodiments (not specifically illustrated), after the planarization process, top surfaces of the die connectors 56 and the dielectric layer 58 are substantially coplanar (within process variations) such that they are level with one another. The die connectors 56 and the dielectric layer 58 are exposed at the front-side 50F of the integrated circuit die 50.

In some embodiments, the integrated circuit die 50 is a stacked device that includes multiple semiconductor substrates 52. For example, the integrated circuit die may be a memory device that includes multiple memory dies such as a hybrid memory cube (HMC) device, a high bandwidth memory (HBM) device, or the like. In such embodiments, the integrated circuit die 50 includes multiple semiconductor substrates 52 interconnected by through vias, such as through-substrate vias (TSVs) (e.g., through-silicon vias). Each of the semiconductor substrates 52 may (or may not) have a separate interconnect structure 54.

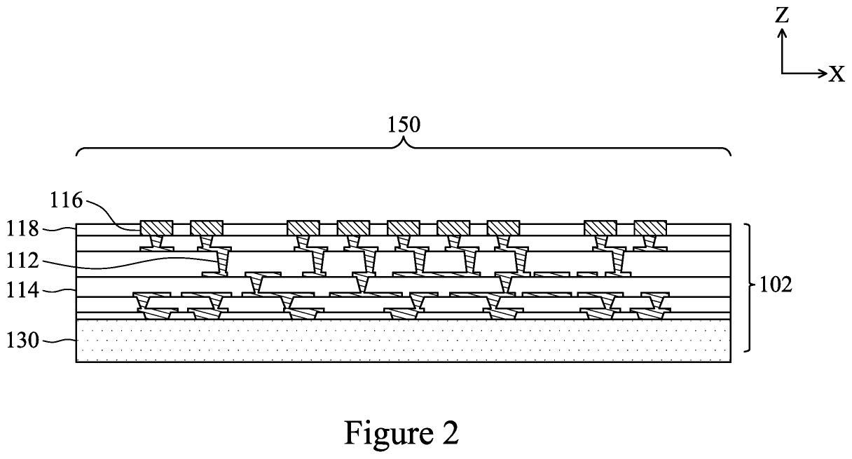

FIGS. 2-9B are views of intermediate stages in the manufacturing of integrated circuit packages 100, in accordance with some embodiments. FIGS. 2-7F are cross-sectional views of a process for forming package components 150, such as package components 150 (e.g., which include interposers 102) attached to package substrates 120, for chip-on-wafer-on-substrate (CoWoS) devices. The package components 150 may be chip-on-wafer (CoW) package components.

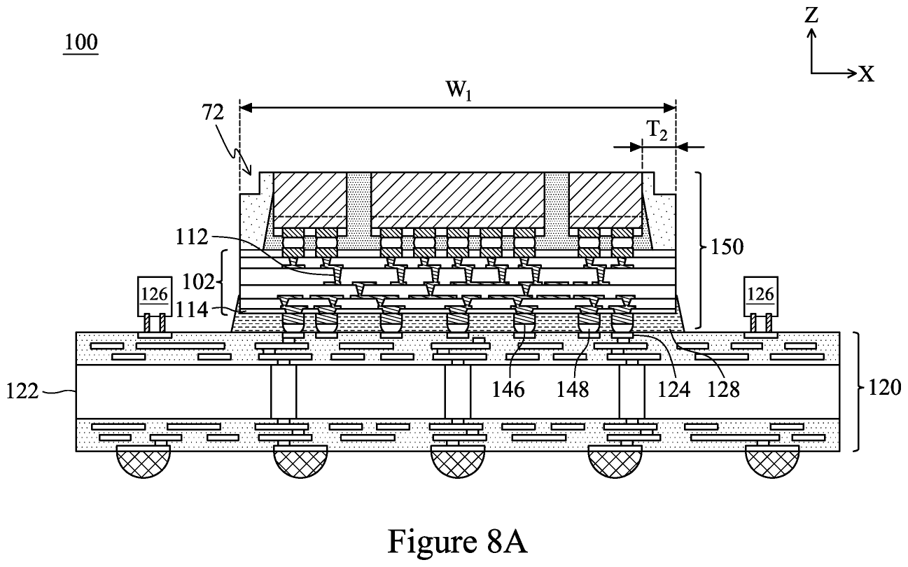

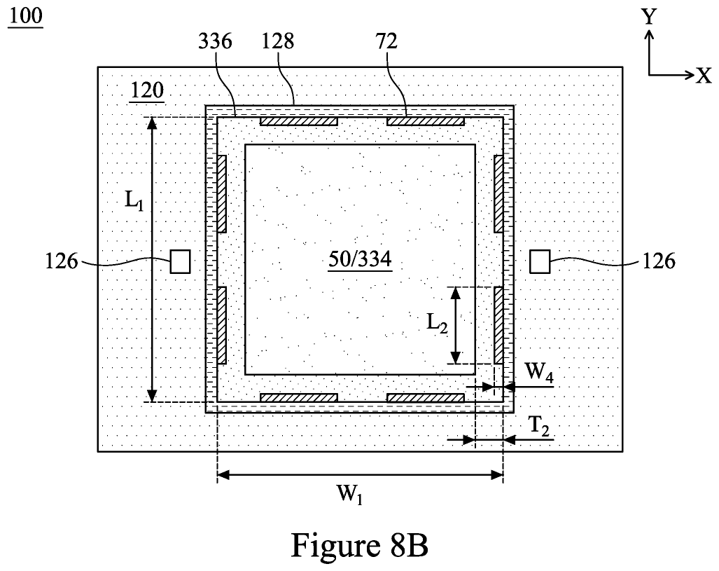

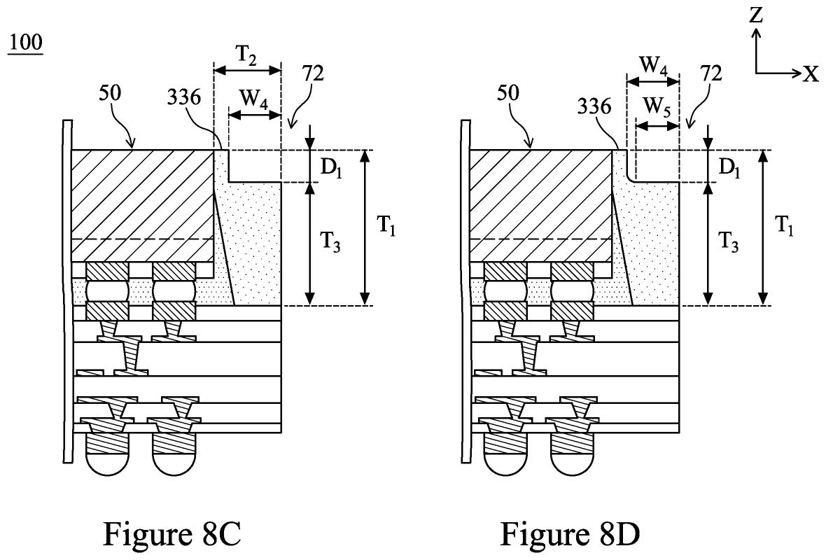

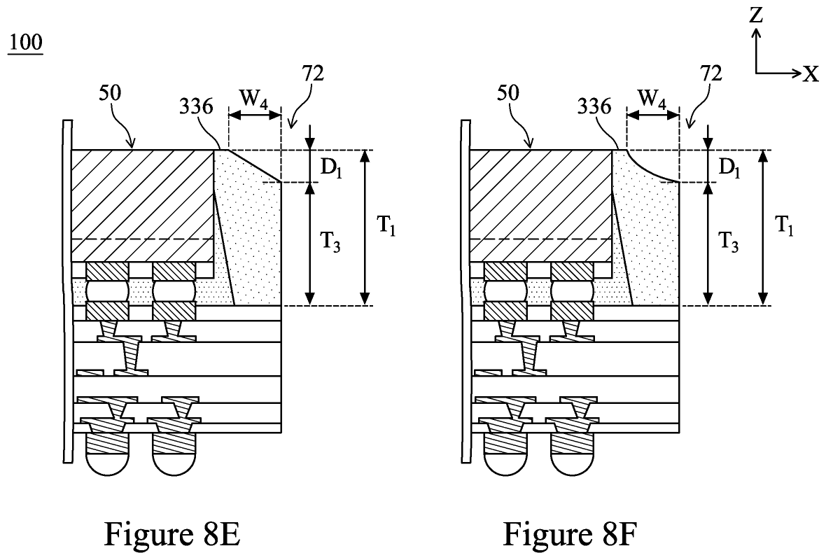

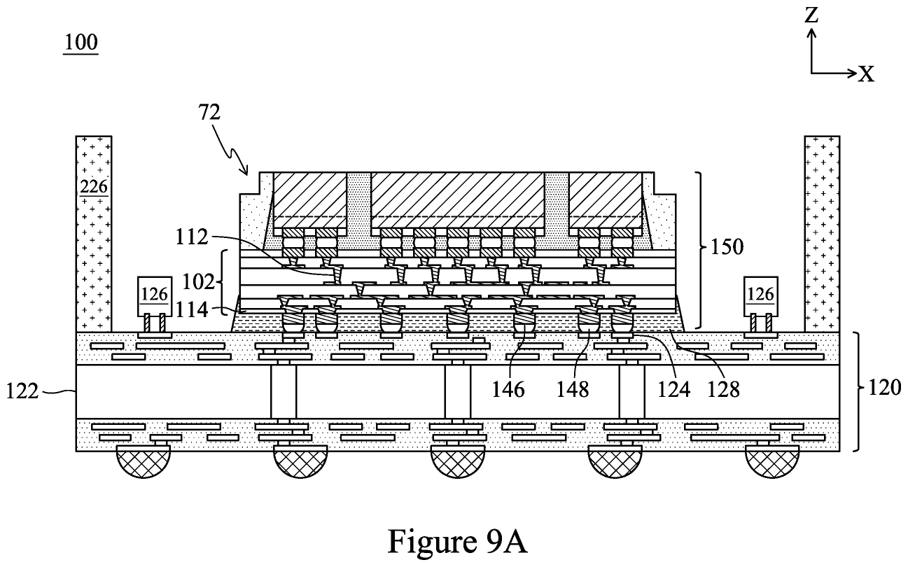

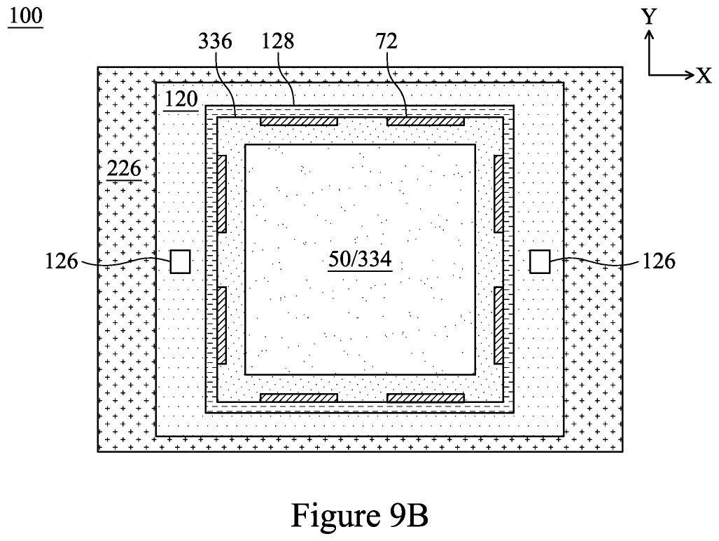

The integrated circuit packages 100 (see FIGS. 9A-9B) will be formed by initially packaging integrated circuit dies 50 on an interposer 102 to form package components 150. In some embodiments, the interposer 102 may be formed over a carrier wafer 130, which may be removed in a subsequent step. Unless otherwise noted, one package region of the interposer 102 is shown for illustrative purposes, but it should be appreciated that any quantity of package regions can be simultaneously processed to form any quantity of package components 150 and singulated to form the individual package components 150 (see FIGS. 8A-8B). The package components 150 will then be attached to package substrates 120 (see FIGS. 8A-8B) to form the integrated circuit packages 100.

In FIG. 2, the interposer 102 is formed over a carrier wafer 130. For example, the interposer 102 may include a plurality of metallization layers 112 embedded in a plurality of dielectric layers 114. Acceptable dielectric materials for the dielectric layers 114 include a polymer such as polybenzoxazole (PBO), polyimide, a benzocyclobuten (BCB) based polymer, or the like. Other dielectric materials may also be used, including oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. The metallization layers 112 may include conductive lines and conductive vias connecting levels of conductive lines to one another. The metallization layers 112 may be formed of a conductive material, such as a metal, such as copper, cobalt, aluminum, gold, combinations thereof, or the like.

As an example to form the interposer 102 in this embodiment, a first of the dielectric layers 114 is formed over the carrier wafer 130. In some embodiments, the carrier wafer 130 is a substrate such as a bulk semiconductor or a glass substrate. In some embodiments, the interposer 102 may be formed over an adhesive layer (not specifically illustrated) on the carrier 130, which may be a laser- and/or thermal-release material which loses its adhesive property when exposed to certain wavelengths of light and/or heated. For example, the adhesive layer may be a light-to-heat-conversion (LTHC) release coating comprising an epoxy, a polyimide, an acrylic, the like, in an acetate and/or alcohol solvent, for example, or a suitable material.

Openings are formed in the first of the dielectric layers 114, and a seed layer (not separately illustrated) is formed over the first of the dielectric layers 114 and in the openings over the exposed surfaces of the carrier wafer 130. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to a first of the metallization layers 112. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the first of the metallization layers 112. These steps may be repeated to form a second of the dielectric layers 114, a second of the metallization layers 112, and so on until all of the metallization layers 112 and the dielectric layers 114 of the interposer 102 are formed. In some embodiments (not specifically illustrated), the interposer 102 (e.g., the metallization layers 112 and the dielectric layers 114) may be formed by a damascene process, such as a single damascene process, a dual damascene process, or the like.

In some embodiments, die connectors 116 and a dielectric layer 118 are formed over the metallization layers 112 and the dielectric layers 114. Specifically, the interposer 102 may include die connectors 116 and a dielectric layer 118 that are similar to those of the integrated circuit die 50 described for FIG. 1. For example, the die connectors 116 and the dielectric layer 118 may be part of an upper metallization layer 112 of the interposer 102.

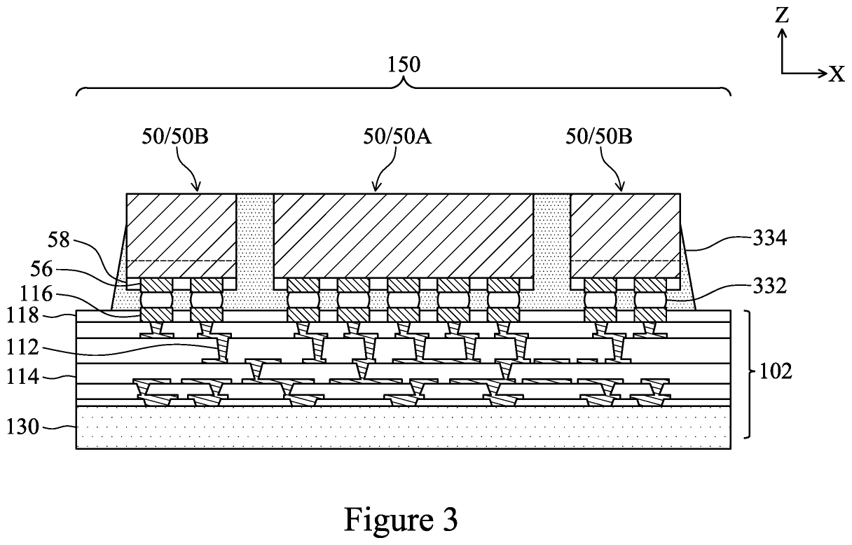

In FIG. 3, integrated circuit dies 50 (e.g., a first integrated circuit die 50A and one or more of second integrated circuit dies 50B) are attached to the interposer 102. In the embodiments shown, multiple integrated circuit dies 50 are placed adjacent one another, including the first integrated circuit die 50A and the second integrated circuit dies 50B, where the first integrated circuit die 50A is between the second integrated circuit dies 50B. In some embodiments, the first integrated circuit die 50A is a logic device, such as a CPU, GPU, or the like, and the second integrated circuit dies are memory devices, such as DRAM dies, HMC modules, HBM modules, or the like. In some embodiments, the first integrated circuit die 50A is the same type of device (e.g., SoCs) as the second integrated circuit dies 50B.

In the illustrated embodiment, the integrated circuit dies 50 are attached to the interposer 102 with conductive connectors 332, such as solder bonds. The conductive connectors 332 may be formed of a conductive material that is reflowable, such as solder, copper, aluminum, gold, nickel, silver, palladium, tin, the like, or a combination thereof. In some embodiments, the conductive connectors 332 are formed by initially forming a layer of solder through methods such as evaporation, electroplating, printing, solder transfer, ball placement, or the like on the die connectors 116. Once a layer of solder has been formed on the die connectors 116, a reflow may be performed in order to shape the conductive connectors 332 into desired bump shapes. Attaching the integrated circuit dies 50 to the interposer 102 may include using, for example, a pick and place tool to place the integrated circuit dies 50 on the interposer 102 and reflowing the conductive connectors 332. The conductive connectors 332 form joints between corresponding die connectors 116 of the interposer 102 and die connectors 56 of the integrated circuit dies 50, electrically connecting the interposer 102 to the integrated circuit dies 50.

An underfill 334 may be formed around the conductive connectors 332, and between the interposer 102 and the integrated circuit dies 50. The underfill 334 may reduce stress and protect the joints resulting from the reflowing of the conductive connectors 332. The underfill 334 may be formed of an underfill material such as a molding compound, epoxy, or the like. The underfill 334 may be formed by a capillary flow process after the integrated circuit dies 50 are attached to the interposer 102, or may be formed by a suitable deposition method before the integrated circuit dies 50 are attached to the interposer 102. The underfill 334 may be applied in liquid or semi-liquid form and then subsequently cured.

In other embodiments (not specifically illustrated), the integrated circuit dies are attached to the interposer 102 with direct bonds. For example, hybrid bonding, fusion bonding, dielectric bonding, metal bonding, or the like may be used to directly bond corresponding dielectric layers 58, 118 and/or die connectors 56, 116 of the integrated circuit dies 50 and the interposer 102 without the use of adhesive or solder. The underfill 334 may be omitted when direct bonding is used. Further, a mix of bonding techniques could be used, e.g., some integrated circuit dies 50 could be attached to the interposer 102 by solder bonds, and other integrated circuit dies 50 could be attached to the interposer 102 by direct bonds.

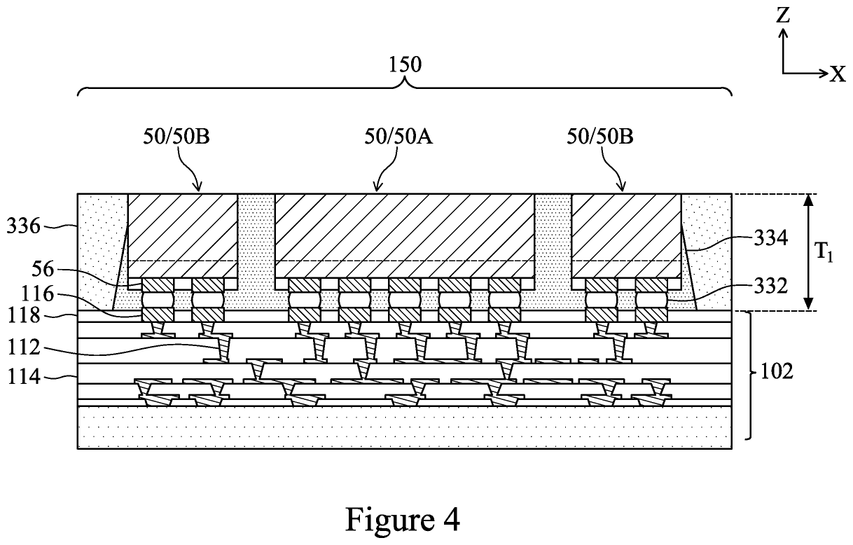

In FIG. 4, an encapsulant 336 is formed over the interposer 102 and on and around the integrated circuit dies 50. After formation, the encapsulant 336 encapsulates the integrated circuit dies 50, and the underfill 334 (if present) or the conductive connectors 332. The encapsulant 336 may be a molding compound, epoxy, or the like. The encapsulant 336 may be applied by compression molding, transfer molding, or the like, and is formed over the interposer 102 such that the integrated circuit dies 50 are buried or covered. The encapsulant 336 may be applied in liquid or semi-liquid form and then subsequently cured. The encapsulant 336 may be thinned to expose the integrated circuit dies 50. The thinning process may be a grinding process, a chemical-mechanical polish (CMP), an etch-back, combinations thereof, or the like. After the thinning process, the top surfaces of the integrated circuit dies 50 and the encapsulant 336 are coplanar (within process variations) such that they are level with one another. The thinning is performed until a desired amount of the integrated circuit dies 50 and/or the encapsulant 336 has been removed. For example, the encapsulant 336 may have a thickness T₁ over the interposer 102 ranging from 50 μm to 780 μm. In addition, a height of the integrated circuit dies 50 above the interposer 102 may be the same as the thickness T₁ of the encapsulant 336.

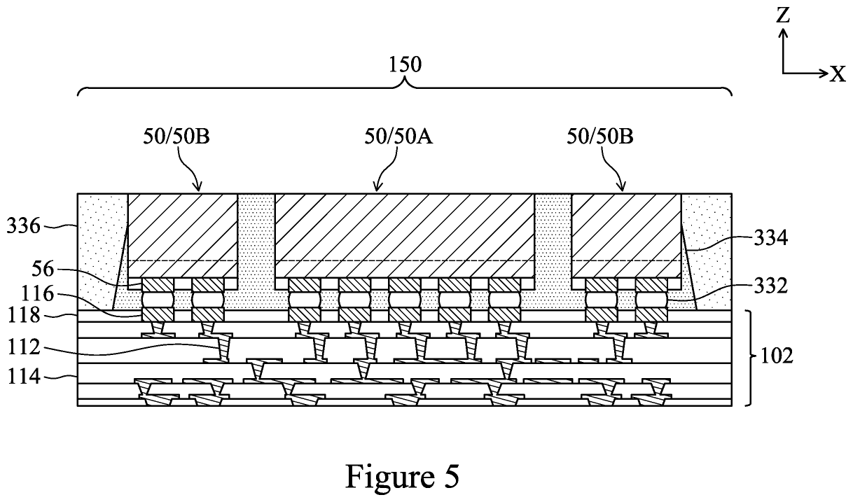

In FIG. 5, the carrier wafer 130 is removed from the interposer 102 to expose the interposer 102 (e.g., the first of the metallization layers 112 and the first of the dielectric layers 114). For example, in embodiments in which an adhesive layer (not specifically illustrated) is used to hold the interposer 102 to the carrier wafer 130, a debonding process may be performed by, e.g., projecting a light such as a laser light or an ultraviolet (UV) light on the adhesive layer so that the adhesive layer decomposes from the energy and/or the heat of the light, and the carrier wafer 130 can be removed. Optionally, an insulating layer (not specifically illustrated) may be formed on the back surface of the interposer 102. The insulating layer may be formed of a silicon-containing insulator, such as, silicon nitride, silicon oxide, silicon oxynitride, or the like, and may be formed by a suitable deposition method such as spin coating, CVD, plasma-enhanced CVD (PECVD), high density plasma CVD (HDP-CVD), or the like. For example, the insulating layer may serve as a passivation layer to protect otherwise exposed features of the metallization layer 112.

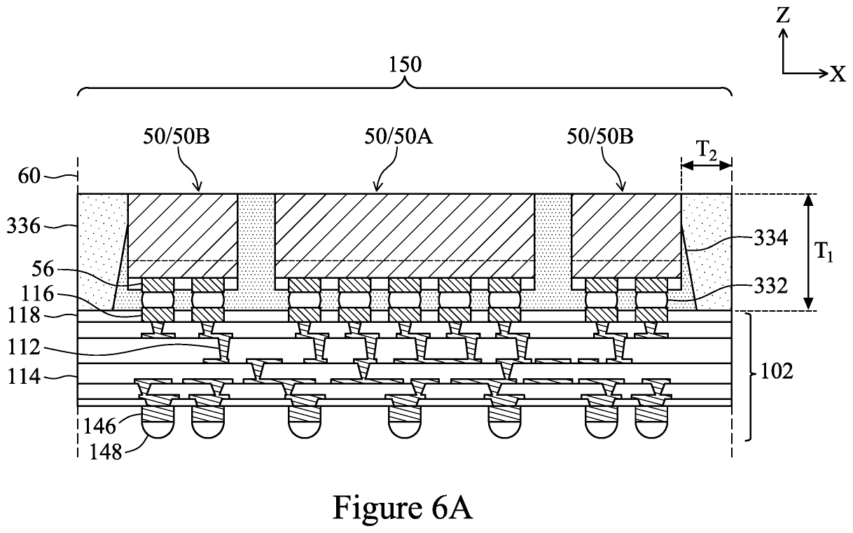

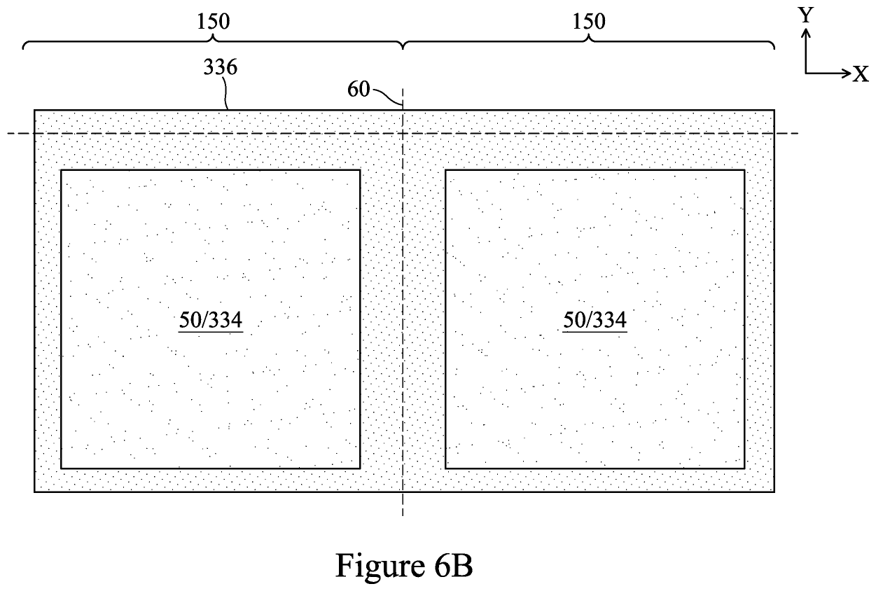

In FIGS. 6A-6B, under-bump metallizations (UBMs) 146 are formed on the exposed surfaces of the interposer 102 (e.g., the metallization layer 112), and conductive connectors 148 are formed on the UBMs 146. If the insulating layer is present, before forming the UBMs 146 and the conductive connectors 148, the insulating layer may be patterned to form openings to expose the first of the metallization layers 112.

FIG. 6B illustrates a top-down view (e.g., of the X-Y plane) of adjacent package components 150. As noted above, the previous processes may be performed at a wafer level wherein multiple packages are formed and later singulated into individual packages. The dotted lines indicate scribe regions 60 within the encapsulant 336 which separate one package component 150 from adjacent package components 150. Note that each package component 150 is illustrated without distinguishing between the first integrated circuit die 50A, the one or more of the second integrated circuit dies 50B, and regions therebetween such as the underfill 334 (if present).

As an example to form the UBMs 146 in this embodiment, a seed layer (not separately illustrated) is formed over the exposed surfaces of the interposer 102. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the UBMs 146. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the UBMs 146.

Further, conductive connectors 148 are formed on the UBMs 146. The conductive connectors 148 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 148 may include a conductive material such as solder, copper, aluminum, gold, nickel, silver, palladium, tin, the like, or a combination thereof. In some embodiments, the conductive connectors 148 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 148 comprise metal pillars (such as copper pillars) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

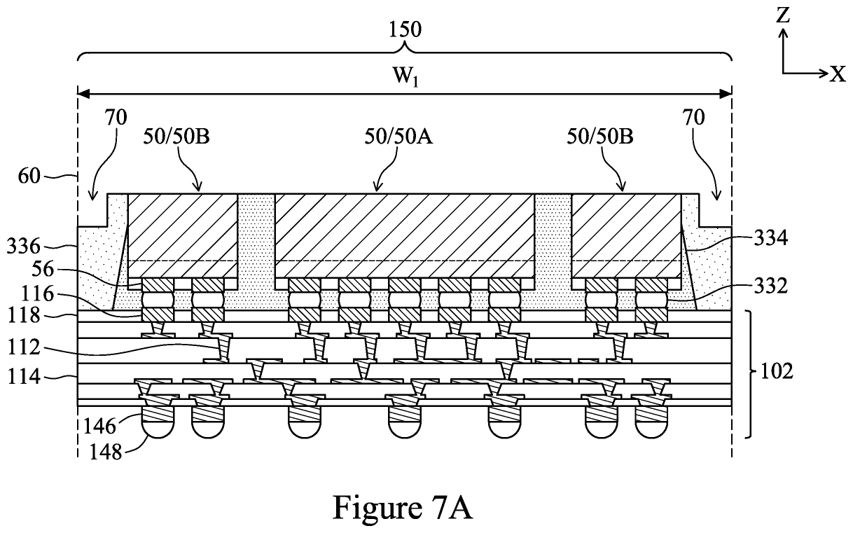

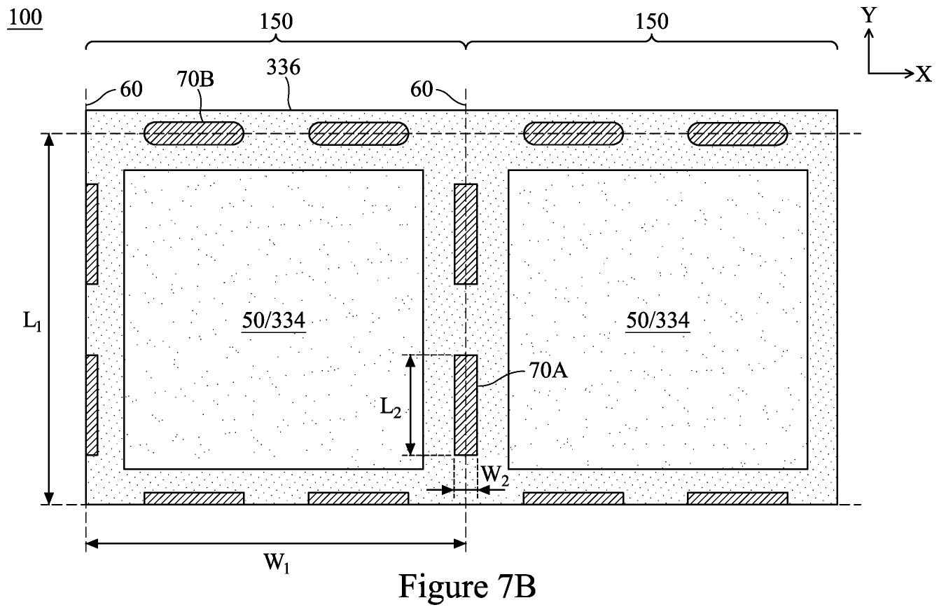

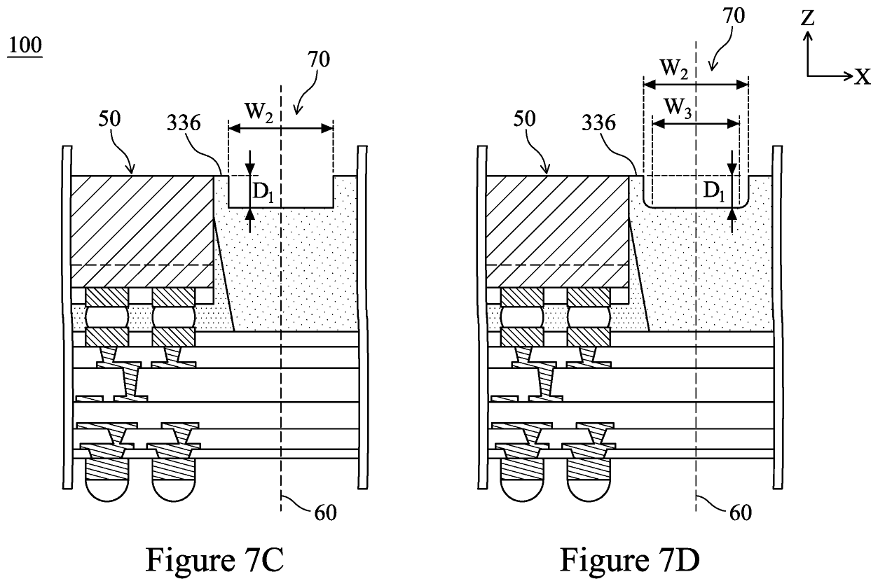

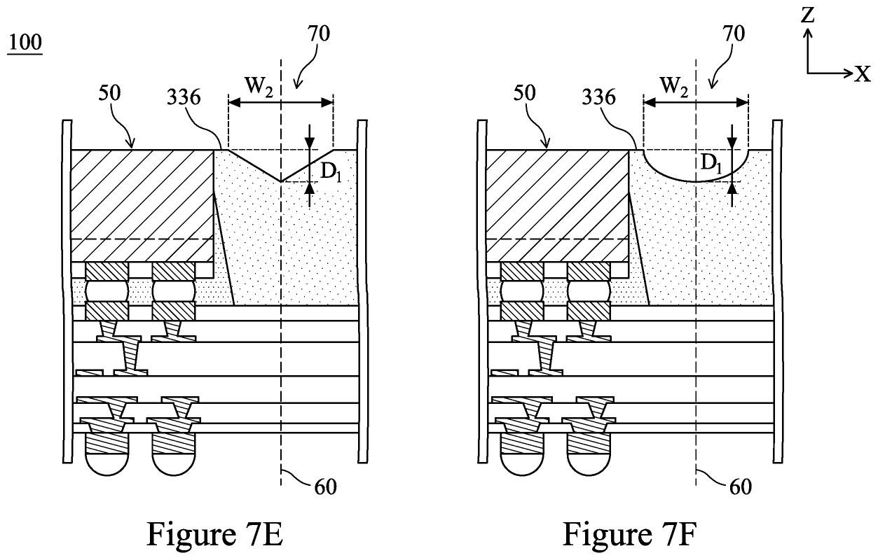

In FIGS. 7A-7F, the encapsulant 336 is laser etched, cut, or engraved along portions of the scribe regions 60 to form recesses 70. In some embodiments, the laser etching may be a high-precision laser etching or a suitable method to form the recesses partially below the top surface of the encapsulant 336 at a consistent depth.

As a result of the laser etching, upper surfaces of the recesses 70 may be below the top surfaces of the encapsulant and the integrated circuit dies 50. The recesses 70 may be formed along only portions of the scribe regions 60. In some embodiments, the recesses 70 may be formed along an entirety of some of the scribe regions 60 adjacent to some of the package components 150. In addition, the recesses may be formed along entireties of all of the scribe regions 60 (e.g., all four sides) adjacent to the package components 150.

FIG. 7B illustrates a top-down view (e.g., of the X-Y plane) of adjacent package components 150. In some embodiments, each of the recesses 70A may have a rectangular shape (e.g., with straight or rounded corners) with a length L₂ along a corresponding scribe region 60. In some embodiments, each of the recesses 70B may have an oval or elliptical shape with the length L₂ (e.g., a major diameter) along the corresponding scribe region 60. In addition, the recess 70 (e.g., either of the recesses or 70B) may straddle two adjacent package components 150. Opposing sidewalls of the recess 70 along edges substantially parallel to the corresponding scribe region 60 may be mirror images of one another. As indicated, outer edges of the encapsulant 336 for one of the package regions 150 may have a length L₁ and a width W₁, which may be the same or different. In addition, the recess 70 may have a length L₂ along the corresponding scribe region 60 and a width W₂ perpendicular to the corresponding scribe region 60.

Referring to FIGS. 7C-7F, the shapes of the recesses 70 described above may correspond to the shapes illustrated in these side views or cross-sections (e.g., the X-Z plane and/or Y-Z plane). Although not specifically illustrated, the other two opposing sidewalls of the recess 70 (e.g., substantially perpendicular with the corresponding scribe region 60) may also be mirror images of one another. In some embodiments, these other two opposing sidewalls may have a same or similar shape as the former two opposing sidewalls or may be substantially vertical. In some embodiments, the etching process may be designed to angle the sidewalls by 0 degrees to 60 degrees from vertical (e.g., from perpendicular to the top surfaces of the encapsulant 336 and the integrated circuit dies 50).

In FIG. 7C, the etching may form the recesses 70 with a substantially rectangular profile along the scribe region 60 between adjacent package components 150. For example, the recess 70 may be formed with a width W₂ and to a depth D₁. As illustrated, the width W₂ may be substantially the same through the depth D₁ if the sidewalls are substantially vertical.

In FIG. 7D, the etching may form the recesses 70 with a substantially rectangular profile and rounded corners along the scribe region 60 between adjacent package components 150. For example, the recess 70 may be formed with an uppermost width W₂, with a lowermost width W₃, and to a depth D₁. As illustrated, the lowermost width W₃ is less than the uppermost width W₂ due to the rounded corners at the bottom of the recess 70.

In FIG. 7E, the etching may form the recesses 70 with a substantially triangular profile (e.g., forming a V-shape) along the scribe region 60 between adjacent package components 150. For example, the recess 70 may be formed with an uppermost width W₂ and to a depth D₁. As illustrated, the recess 70 converges at a point toward the bottom of the recess 70.

In FIG. 7F, the etching may form the recesses 70 with a curved or an elliptical profile (e.g., forming a U-shape) along the scribe region 60 between adjacent package components 150. For example, the recess 70 may be formed with an uppermost width W₂ and to a depth D₁. As illustrated, the recess 70 slopes toward a point or narrow width at the bottom of the recess 70.

FIGS. 8A-9B illustrate various additional steps in the manufacturing of embodiment packages. For example, the structure illustrated in FIGS. 7A-7B is singulated along the scribe regions 60 to separate the package components 150, and the package components 150 are attached to package substrates 120, and other devices, such as passive devices 126 and a ring assembly 226, may be attached to the package substrates 120, thus forming the integrated circuit packages 100. A single package component 150, a single package substrate 120, and a single integrated circuit package 100 are illustrated. It should be appreciated that multiple package components can be simultaneously processed to form multiple integrated circuit packages 100.

In FIGS. 8A-8F, the package component 150 is attached to a package substrate 120 using the conductive connectors 148. In some embodiments, a singulation process is performed by cutting along the scribe regions 60 illustrated in FIGS. 7A-7B. In addition, the singulation process cuts through the recesses 70 to form recessed regions 72 along the outer edges of the encapsulant 336 of the package component 150. The singulation process may include sawing, dicing, or the like. For example, the singulation process can include sawing the encapsulant 336, the interposer 102 (e.g., the dielectric layers 114), and the dielectric layer 118. The singulation process singulates the package component 150 from adjacent package components 150. As a result of the singulation process, the outer sidewalls of the interposer 102 and the encapsulant 336 are laterally coterminous (within process variations). After singulation, the encapsulant 336 may have a lateral thickness T₂ from outer sidewalls of the integrated circuit dies ranging from 50 μm to 5000 μm.

Referring to FIG. 8A, the package substrate 120 includes a substrate core 122, which may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations thereof, or the like, may also be used. Additionally, the substrate core 122 may be a SOI substrate. Generally, an SOI substrate includes a layer of a semiconductor material such as epitaxial silicon, germanium, silicon germanium, SOI, SGOI, or combinations thereof. In another embodiment, the substrate core 122 is an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for the substrate core 122.

The substrate core 122 may include active and passive devices (not separately illustrated). Devices such as transistors, capacitors, resistors, combinations thereof, and the like may be used to generate the structural and functional requirements of the design for the system. The devices may be formed using any suitable methods.

The substrate core 122 may also include metallization layers and vias, and bond pads 124 over the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material, and may be formed through any suitable process (such as deposition, damascene, or the like). In some embodiments, the substrate core 122 is substantially free of active and passive devices.

The conductive connectors 148 are reflowed to attach the UBMs 146 of the interposer 102 to the bond pads 124 of the package substrate 120. The conductive connectors 148 connect the package component 150 (e.g., the metallization layers 112 of the interposer 102) to the package substrate 120 (e.g., metallization layers of the substrate core 122). Thus, the package substrate 120 is electrically connected to the integrated circuit dies 50. In some embodiments, passive devices (e.g., surface mount devices (SMDs), not specifically illustrated) may be attached to the package component 150 (e.g., bonded to the UBMs 146) prior to mounting on the package substrate 120. In such embodiments, the passive devices may be bonded to a same surface of the package component 150 as the conductive connectors 148. In some embodiments, passive devices 126 (e.g., SMDs) may be attached to the package substrate 120, e.g., to the bond pads 124. For example, the passive devices 126 may be attached to the package substrate 120 before attaching the package component 150 to the package substrate 120.

In some embodiments, an underfill 128 is formed between the package component 150 and the package substrate 120, surrounding the conductive connectors 148. The underfill 128 may be formed by a capillary flow process after the package component 150 is attached or may be formed by any suitable deposition method before the package component 150 is attached. The underfill 128 may be a continuous material extending from the package substrate 120 to the interposer 102 (e.g., to the first of the dielectric layers 114). In some embodiments, some of the passive devices 126 may be attached to the package substrate 120 after forming the underfill 128.

FIG. 8B illustrates a top-down view (e.g., of the X-Y plane) of the singulated package component 150 attached to the package substrate 120. As illustrated, the underfill 128 may extend beyond sidewalls (e.g., outer edges or a perimeter) of the encapsulant 336 (and the interposer 102) of the package component 150. As further illustrated, upon singulation, the recesses 70 are converted to the recessed regions 72 along the outer edges (e.g., portions of the perimeter) of the encapsulant 336 of the package component 150. Each corner region of the encapsulant 336 in the top-down view corresponds to two proximal portions of the outer edges of the encapsulant 336 that may each contain one or more of the recessed regions 72. Although two recessed regions 72 are illustrated in each of the corner regions, more than two recessed regions 72 may be formed in some or all of the four corner regions. Each recessed region 72 may be short or long segments having, for example, a rectangular shape as illustrated. In some embodiments, each recessed region 72 may have a rectangular shape (e.g., a rectangle, such as the recesses 70A in FIG. 7B, cut in half along the length) with the two internal corners being rounded. In some embodiments (not specifically illustrated), each recessed region 72 may have a half-oval shape (e.g., an elongated oval shape, such as the recesses 70B in FIG. 7B, cut in half along the major diameter, which corresponds to the outer edge of the encapsulant 336).

FIGS. 8C-8F illustrate the recessed regions 72 after singulating the structures provided in FIGS. 7C-7F, respectively. As such, in these side views or cross-sections (e.g., the X-Z plane and/or Y-Z plane), the recessed regions 72 may have shapes which correspond to the shapes of the recesses 70 (see FIGS. 7C-7F) after singulation, albeit cut in half.

In FIG. 8C, the recessed regions 72 are formed by singulating through the encapsulant 336 and the recesses 70 of the package component 150 of FIG. 7C (e.g., with a substantially rectangular profile). For example, the recessed region 72 may have a width W₄ being about half of the width W₂ and be formed to the depth D₁. As illustrated, the width W₄ may be substantially the same through the depth D₁ if the sidewall is substantially vertical.

In FIG. 8D, the recessed regions 72 are formed by singulating through the encapsulant 336 and the recesses 70 of the package component 150 of FIG. 7D (e.g., with a substantially rectangular profile and rounded corners). For example, the recessed region 72 may have an uppermost width W₄ being about half of the width W₂, a lowermost width W₅ being about half of the width W₃, and the depth D₁. As illustrated, the lowermost width W₅ is less than the uppermost width W₄ due to the rounded corners at a lowermost point of the recessed region 72.

In FIG. 8E, the recessed regions 72 are formed by singulating through the encapsulant 336 and the recesses 70 of the package component 150 of FIG. 7E (e.g., with a substantially triangular profile (see FIG. 7E). For example, the recessed region 72 may have an uppermost width W₄ being about half of the width W₃ and be formed to the depth D₁. As illustrated, the recessed region 72 has a linear slope toward a lowermost point of the recessed region 72 (e.g., a flat beveled edge of the encapsulant).

In FIG. 8F, the recessed regions 72 are formed by singulating through the encapsulant 336 and the recesses 70 of the package component 150 of FIG. 7F (e.g., with a curved or an elliptical profile. For example, the recessed region 72 may have an uppermost width W₄ being about half of the width W₂ and be formed to the depth D₁. As illustrated, the recessed region 72 has a concave slope toward a lowermost point of the recessed region 72 (e.g., a concave beveled edge of the encapsulant 336).

In accordance with some embodiments of the above-described shapes or profiles of the recessed regions 72, the encapsulant 336 has a thickness T₁ ranging from 50 μm to 780 μm (e.g., a same measurement as a height of the integrated circuit dies 50 above the interposer 102). In addition, a ratio of the depth D₁ of the recessed region 72 to the thickness T₁ of the encapsulant 336 is greater than 0.1 and less than 0.99. Further, a thickness T₃ of the encapsulant 336 at the recessed region 72 is greater than 0 and less than the thickness T₁ of the encapsulant 336.

The recessed regions 72 advantageously reduce or control stress allocation during and after the singulation and attachment processes. For example, reflowing and bonding the conductive connectors 148 in order to attach the package component 150 to the package substrate 120 may include increasing and decreasing temperatures of the package component 150. In addition, thermal cycle testing performed on the completed integrated circuit package 100 may also include temperature fluctuations. In both cases, differences in the coefficients of thermal expansion (CTEs) between the encapsulant 336 and bulk portions of the integrated circuit dies 50 may form stress points in the encapsulant 336. For example, the corners of the encapsulant 336 and portions adjacent to the integrated circuit dies 50 may experience elevated stress levels. The recessed regions 72 of the encapsulant 336 may reduce the elevated stress levels by up to 5%, which is sufficient to avoid/reduce inducement of cracks in the encapsulant 336.

The shape or profile of the recessed regions 72 in these side views or cross-sections may be selected to achieve varying benefits. For example, the rectangular shape of the recessed regions 72 (see FIGS. 8C and 8D) minimizes/reduces the amount of material of the encapsulant 336 that is proximal to the integrated circuit dies 50, thereby minimizing/reducing the effect of a CTE mismatch. In particular, the rounded corners on the rectangular shape (see FIG. 8D) provide gentler slopes to minimize/reduce weak points that may be introduced from the laser etching or otherwise. In addition, the linear slope of the recessed regions 72 (see FIG. 8E) results in comparatively more of the material of the encapsulant 336 to be proximal to the integrated circuit dies 50, while minimizing/reducing the introduction of any weak points from the laser etching or otherwise. Further, the concave slope of the recessed regions 72 (see FIG. 8F) may provide a balance of the above-described benefits by having a shape and an amount of the material of the encapsulant 336 that are middle-grounds between the other shapes and profiles.

In FIGS. 9A-9B, a ring assembly 226 is attached to the package substrate 120 and around the package component 150 and the passive devices 126 (if present). In some embodiments, the ring assembly 226 may have a rigidity greater than that of the package substrate 120 and may be configured as a stiffener ring for constraining the package substrate 120 to alleviate its warpage (due to stress generated during subsequent processing steps or testing, such as thermal cycling) and/or to enhance the robustness of the package substrate 120. In some embodiments, the ring assembly 226 is arranged along the periphery of the package substrate 120 and surrounds the package component 150 and the passives devices 126 above the package substrate 120. In a top-down view (see FIG. 9B), the ring assembly 226 may have a rectangular shape depending, for example, on the size and shape of the package substrate 120. In some embodiments, the ring assembly 226 may be formed over the package substrate 120.

In some embodiments, the ring assembly 226 is attached to the package substrate 120 using an adhesive layer (not specifically illustrated) interposed between a bottom surface of the ring assembly 226 and an upper surface of the package substrate 120. The adhesive layer may be any suitable non-conductive adhesive, epoxy, die attach film (DAF), or the like, and may be applied to the bottom surface of the ring assembly 226 or may be applied over the upper surface of the package substrate 120 before installing the ring assembly 226.

The ring assembly 226 may be made of one or more materials. For example, the ring assembly 226 adjacent to the package substrate 120 may be formed of a rigid material having a CTE similar to that of the underlying package substrate 120, thereby reducing CTE mismatch therebetween and reducing stress (as well as deformation) on the package substrate 120, such as being caused by the ring assembly 226. For example, materials of the ring assembly 226 may include metals such as copper, stainless steel, stainless steel/Ni, the like, and combinations and alloys thereof.

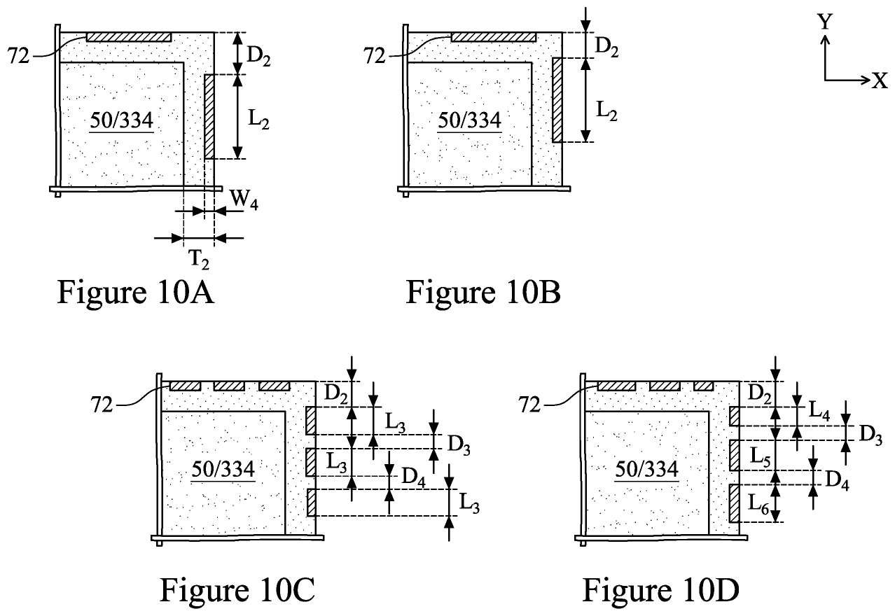

FIGS. 10A-10D illustrate exemplary patterns or layouts in a top-down view (e.g., of the X-Y plane) for forming the recessed regions 72 along the edge regions of the outer edges of the encapsulant 336. The illustrated patterns are merely examples and are not intended to be limiting. In some embodiments, more than one pattern may be applied to the encapsulant 336 of each package component 150. As such, any combination of the above-described patterns may be utilized along the outer edges of the encapsulant 336 for any given package component 150.

Note that FIGS. 10A-10D are depicted and described such that both edge regions of the corresponding corner of the encapsulant 336 have analogous patterns of the recessed regions 72. In some embodiments, any combination of patterns of the recessed regions 72 may be applied to the pair of edge regions.

Referring to FIG. 10A, the recessed region 72 may be a distance D₂ from the corner of the encapsulant 336 that is greater than the thickness T₂ of the encapsulant 336 (e.g., from an outer sidewall of the integrated circuit dies 50). As a result, a larger amount of the encapsulant 336 remains in the corner region to protect the corresponding corner of the integrated circuit dies 50.

Referring to FIG. 10B, the recessed region 72 may be a distance D₂ from the corner of the encapsulant 336 that is less than the thickness T₂ of the encapsulant 336. As a result, the recessed region 72 is closer to high stress points in the corner of the encapsulant 336 and better available to reduce the stress therein.

Referring to FIG. 10C, two or more (e.g., three) recessed regions 72 may be formed along an edge of the encapsulant 336 in proximity to a corresponding corner region. Each of the recessed regions 72 may have a same length L₃ and be separated from another by distances D₃ and D₄. The distance D₃ may be the same as, less than, or greater than the distance D₄. The recessed region 72 most proximal to the corner may be a distance D₂ from the corner of the encapsulant 336, and the distance D₂ may be the same as, greater than, or less than the thickness T₂ of the encapsulant 336.

Referring to FIG. 10D, two or more (e.g., three) recessed regions 72 of varying lengths L₄, L₅, L₆ may be formed along an edge of the encapsulant 336 in proximity to a corresponding corner region. Each of the recessed regions 72 may be separated from another by distances D₃ and D₄. In some embodiments, the lengths L₄, L₅, L₆ increase moving away from the corner of the encapsulant 336. The distance D₃ may be the same as, less than, or greater than the distance D₄. The recessed region 72 most proximal to the corner may be a distance D₂ from the corner of the encapsulant 336, and the distance D₂ may be the same as, greater than, or less than the thickness T₂ of the encapsulant 336.

Although not specifically illustrated, in regard to the above embodiments, the distance D₂ may be the same as the thickness T₂. In addition, the recessed region 72 may be formed along a central portion of the outer edge of the encapsulant 336, and the recessed region 72 may be about the same distance from both corresponding corners of the encapsulant 336.

In accordance with some embodiments of the above-described patterns of the recessed regions 72 in the edge regions, the outer edges of the encapsulant 336 surrounding the integrated circuit dies 50 have a length L₁ and/or width W₁ ranging from 10 mm to 100 mm, wherein the thickness T₂ around the integrated circuit dies 50 ranges from 50 μm to 5000 μm. In addition, the recessed regions 72 may have a length L₂ of less than or equal to one-third of the corresponding length L₁ or width W₁, and the distance D₂ of the recessed region 72 from the most proximal corner may range from 50 μm to 5000 μm (e.g., less than or equal to one-third of the thickness T₂ of the encapsulant 336). Further, a ratio of the width W₄ of the recessed region 72 to the thickness T₂ of the encapsulant 336 is greater than 0.1 and less than 0.99.

In embodiments that follow the descriptions of FIGS. 10C and 10D, the edge region includes more than one recessed region 72, each of the recessed regions 72 may be separated by a distance D₃ or D₄ from one another ranging from 200 μm to 2000 μm. In addition, each of the plurality of recessed regions 72 may have the length L₃ in the same range as the above descriptions for the length L₂ or wherein a sum of the length L₃ of all of these recessed regions 72 may be in the same ranges as described for the length L₂. In some embodiments, each of the plurality of recessed regions 72 may have varying lengths L₄, L₅, L₆, etc., such that length L₄<length L₅<length L₆ and so on. In addition, a sum of the lengths L₄, L₅, L₆, etc. of all of these recessed regions 72 may be in the same ranges as described above for the length L₂.

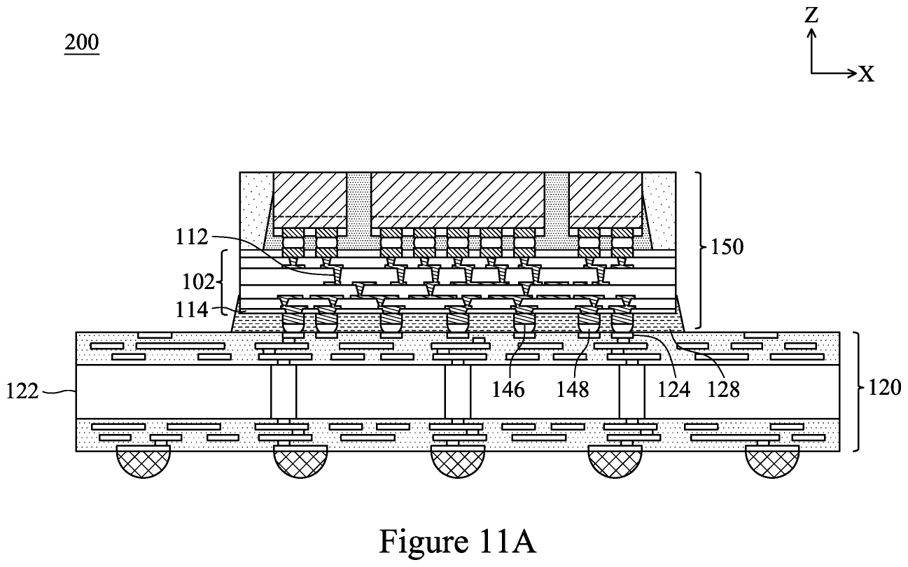

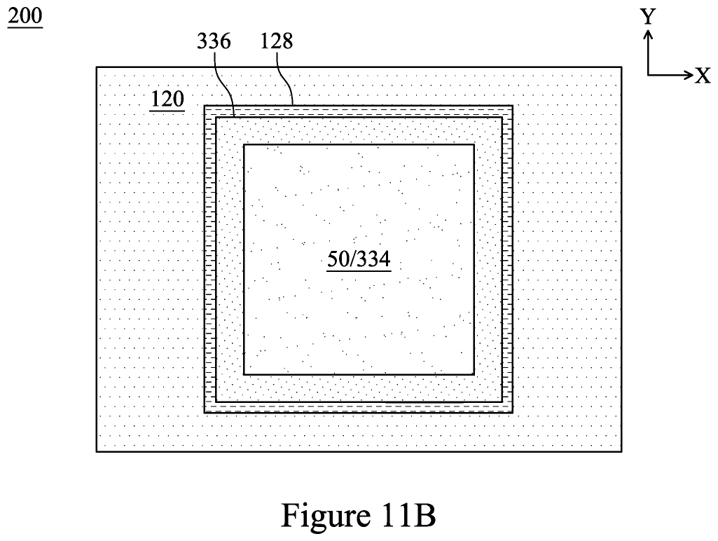

FIGS. 11-13D are views of intermediate stages in the manufacturing of the integrated circuit packages 200, in accordance with some embodiments. For example, the integrated circuit packages 200 will be formed by attaching the package components 150 to the package substrate 120 to form the integrated circuit packages 200 before forming the recessed regions 72 along the outer edges of the encapsulant 336 using, for example, an etch process (e.g., a laser etching).

In FIGS. 11A-11B, similarly as described above, the package component 150 is attached to the package substrate 120 using the conductive connectors 148. For example, the structure illustrated in FIGS. 6A and 6B may be singulated prior to forming the recessed regions 72 as illustrated in FIGS. 8A and 8B by cutting along the scribe regions 60, e.g., around the package components 150. After singulation (and prior to forming the recessed regions 72), the package component 150 is attached to the package substrate 120. The package component 150 may be attached to the package substrate 120 in a similar manner as discussed above with reference to FIGS. 8A and 8B.

FIG. 11B illustrates a top-down view (e.g., of the X-Y plane) of the singulated package component 150 attached to the package substrate 120. As shown, the underfill 128 may extend beyond sidewalls (e.g., the outer edges or perimeter) of the encapsulant 336 of the package component 150. Note that there are not yet recessed regions 72 along the outer edges of the encapsulant 336 of the package component 150.

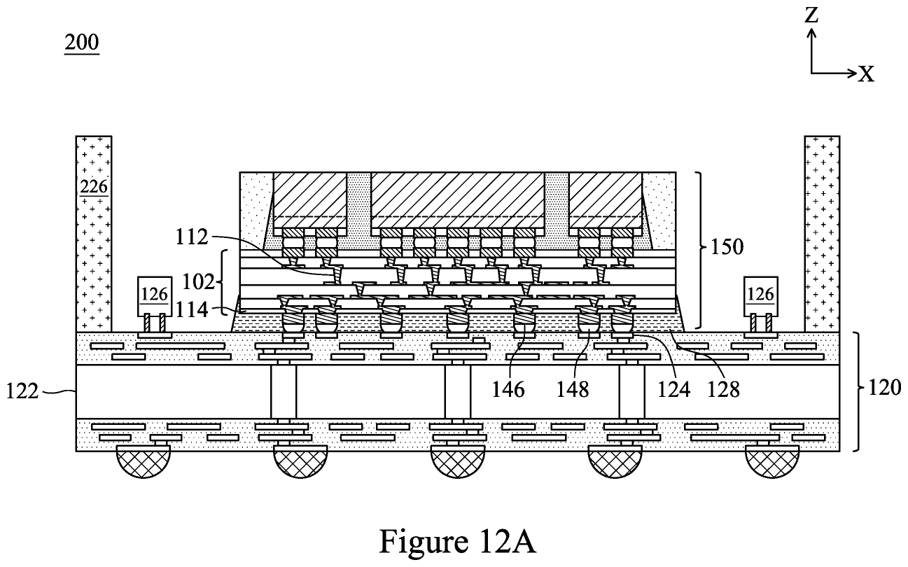

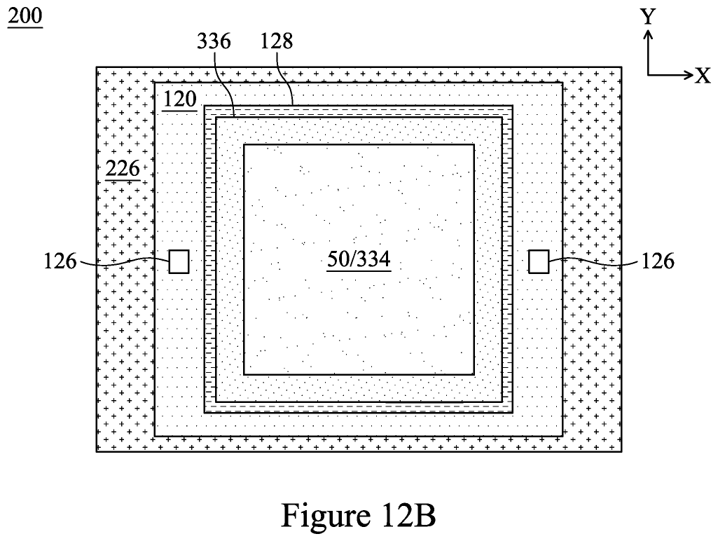

In FIGS. 12A-12B, in some embodiments, the passive devices 126 (e.g., SMDs) may be attached to the package substrate 120, and the ring assembly 226 may be formed over the package substrate 120 and around the package component 150 and the passive devices 126 (if present). For example, the passive devices 126 may be attached to the bond pads 124. In some embodiments (not specifically illustrated), the passive devices 126 may be attached to the package substrate 120 before attaching the package component 150 to the package substrate 120. The passive devices 126 may be attached similarly as described above. In addition, the ring assembly 226 may be formed or attached similarly as described above.

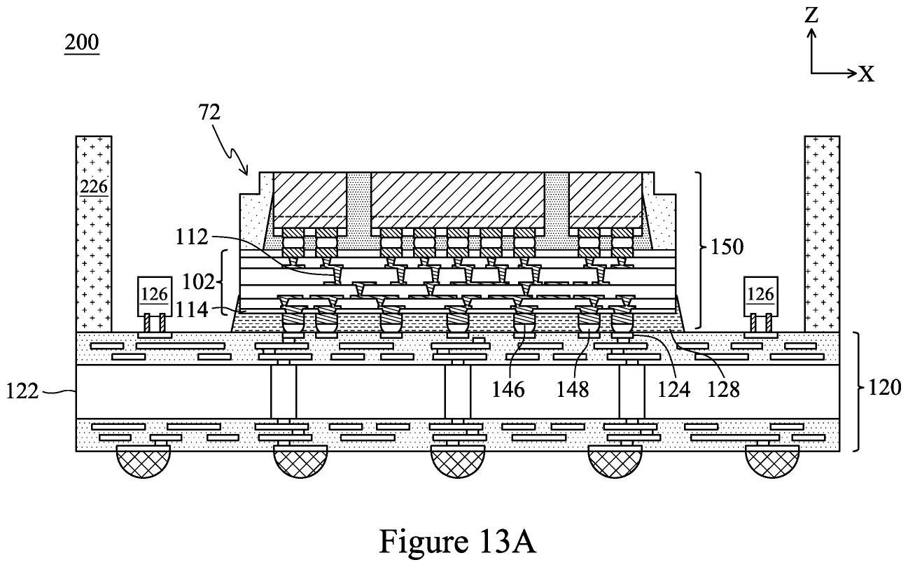

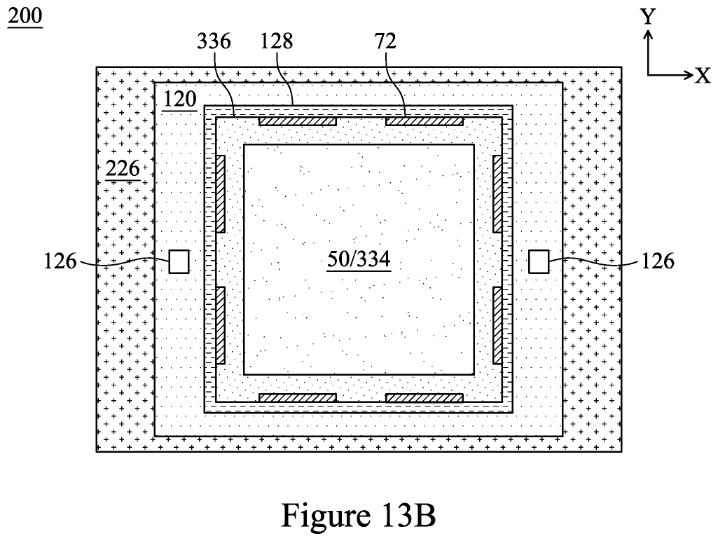

In FIGS. 13A-13B, the encapsulant 336 is laser etched along portions of the outer edges to form the recessed regions 72. The laser etching may be performed similarly as described above in connection with FIGS. 7A-7F. For example, this embodiment may be advantageous when the package components 150 are already singulated or when the integrated circuit package 200 is already assembled. Although not specifically illustrated, the laser etching may be performed before forming or attaching the passive devices 126 and the ring assembly 226 (see FIGS. 12A-12B).

FIG. 13B illustrates a top-down view (e.g., of the X-Y plane) of the package component 150 attached to the package substrate 120 with the recessed regions 72 formed at edge regions of the encapsulant 336. The recessed regions 72 may have similar shapes as those discussed above in connection with FIGS. 8A-8F.

Note that other combinations of patterns for the recessed regions 72 discussed herein and above (e.g., including a lack of recessed regions 72) may be utilized in the corner regions for the package components 150 of either the integrated circuit packages 100 and 200. In some embodiments, diagonal corners of the package components 150 may follow same patterns as one another. In addition, each of the four edges of the perimeter of the encapsulant 336 may utilize same or varying patterns. Further, any combinations of patterns for the recessed regions 72 may be utilized.

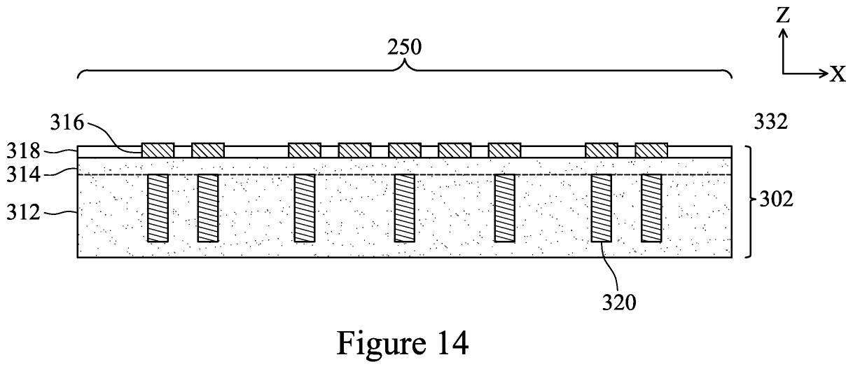

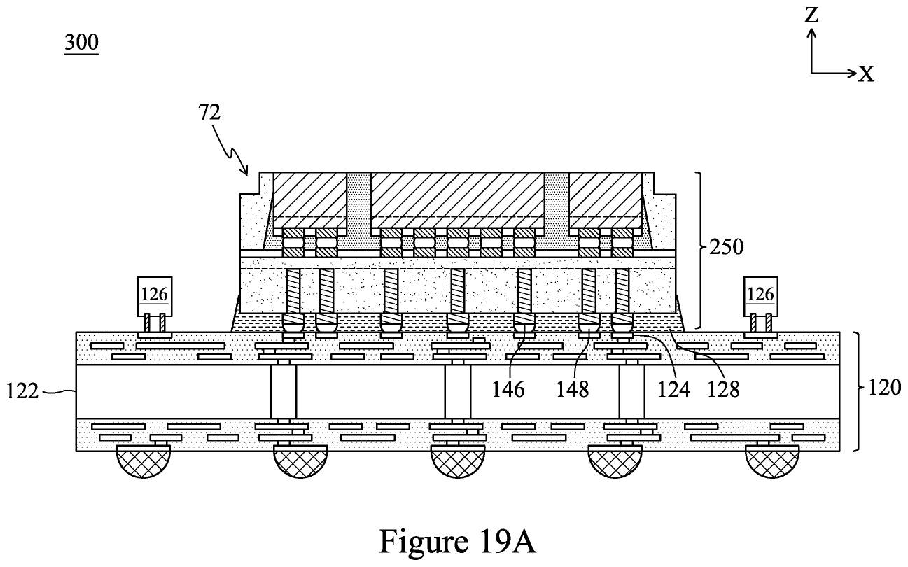

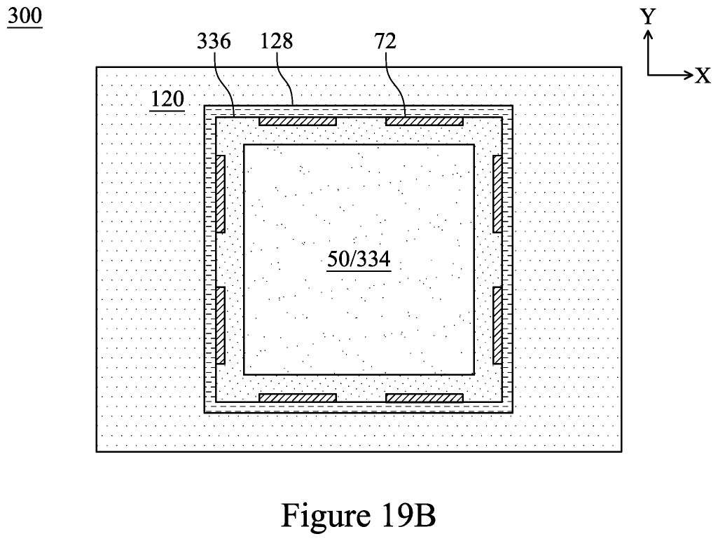

FIGS. 14-20B are views of intermediate stages in the manufacturing of integrated circuit packages 300, in accordance with some embodiments. FIGS. 14-18 are cross-sectional views of a process for forming package components 250. As discussed above, the interposer 102 comprises a build-up interposer formed on a carrier substrate (not specifically illustrated), which is later removed. Other interposers may be used. For example, FIGS. 14-20B illustrate the use of an interposer 302, which includes a substrate and through vias extending through the substrate. The process may include a chip-on-wafer-on-substrate (CoWoS) process. The package components 250 may be chip-on-wafer (CoW) package components. Note that the integrated circuit packages 300 (see FIGS. 19A and 19B) may be formed similarly as described above in connection with the integrated circuit packages 100, unless otherwise stated.

Referring first to FIG. 14, in some embodiments, interposers 302 include a substrate 312, an interconnect structure 314, and conductive vias 320. For example, the substrate 312 may be a bulk semiconductor substrate, a semiconductor-on-insulator (SOI) substrate, a multi-layered semiconductor substrate, or the like. The substrate 312 may include a semiconductor material, such as silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The substrate 312 may be doped or undoped. The interposer 302 may be free of devices. In some embodiments, the interposer 302 includes active and/or passive devices

The interconnect structure 314 is over the substrate 312, and is used to electrically connect the devices (if any) of the substrate 312. The interconnect structure 314 may be formed in a similar manner as the interconnect structure 54. In some embodiments, die connectors 316 and a dielectric layer 318 are at the front-side of the interposer 302. Specifically, the interposer 302 may include die connectors 316 and a dielectric layer 318 that are similar to those of the integrated circuit die 50 and/or the interposer 102 as described above. For example, the die connectors 316 and the dielectric layer 318 may be part of an upper metallization layer of the interconnect structure 314.

The conductive vias 320 extend into the interconnect structure 314 and/or the substrate 312. The conductive vias 320 are electrically connected to metallization layer(s) of the interconnect structure 314. The conductive vias 320 are also sometimes referred to as through vias. As an example to form the conductive vias 320, recesses can be formed in the interconnect structure 314 and/or the substrate 312 by, for example, etching, milling, laser techniques, a combination thereof, and/or the like. A thin dielectric material may be formed in the recesses, such as by using an oxidation technique. A thin barrier layer may be conformally deposited in the openings, such as by CVD, atomic layer deposition (ALD), physical vapor deposition (PVD), thermal oxidation, a combination thereof, and/or the like. The barrier layer may be formed of an oxide, a nitride, a carbide, combinations thereof, or the like. A conductive material may be deposited over the barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from a surface of the interconnect structure 314 or the substrate 312 by, for example, a CMP. Remaining portions of the barrier layer and conductive material form the conductive vias 320.

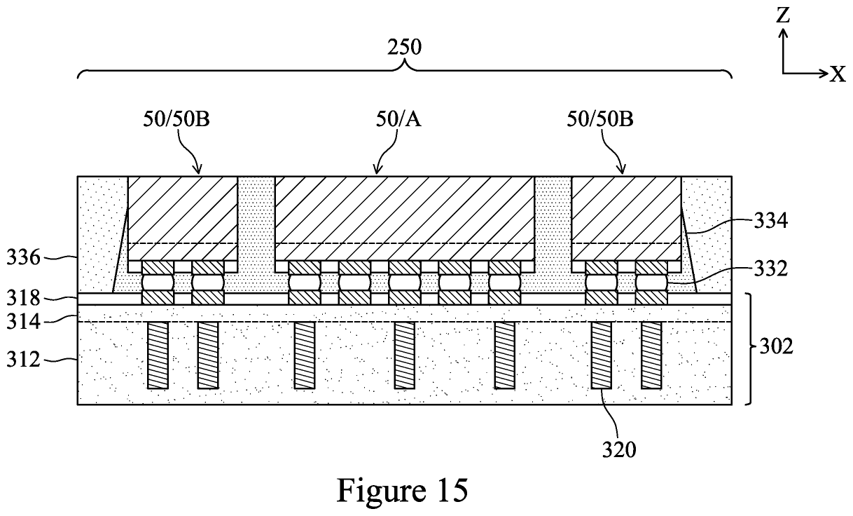

In FIG. 15, integrated circuit dies 50 (e.g., a first integrated circuit die 50A and one or more of second integrated circuit dies 50B) are attached to the interposer 302, similarly as discussed above in connection with the package components 150.

In the illustrated embodiment, the integrated circuit dies 50 are attached to the interposer 302 with conductive connectors 332, such as solder bonds. The conductive connectors 332 may be formed of a conductive material that is reflowable, such as solder, copper, aluminum, gold, nickel, silver, palladium, tin, the like, or a combination thereof. In some embodiments, the conductive connectors 332 are formed by initially forming a layer of solder through methods such as evaporation, electroplating, printing, solder transfer, ball placement, or the like on the die connectors 316. Once a layer of solder has been formed on the die connectors 316, a reflow may be performed in order to shape the conductive connectors 332 into desired bump shapes. Attaching the integrated circuit dies 50 to the interposer 302 may include using, for example, a pick and place tool to place the integrated circuit dies 50 on the interposer 302 and reflowing the conductive connectors 332. The conductive connectors 332 form joints between corresponding die connectors 316 of the interposer 302 and die connectors 56 of the integrated circuit dies 50, electrically connecting the interposer 302 to the integrated circuit dies 50.

An underfill 334 may be formed around the conductive connectors 332, and between the interposer 302 and the integrated circuit dies 50. The underfill 334 may reduce stress and protect the joints resulting from the reflowing of the conductive connectors 332. The underfill 334 may be formed of an underfill material such as a molding compound, epoxy, or the like. The underfill 334 may be formed by a capillary flow process after the integrated circuit dies 50 are attached to the interposer 302, or may be formed by a suitable deposition method before the integrated circuit dies 50 are attached to the interposer 302. The underfill 334 may be applied in liquid or semi-liquid form and then subsequently cured.

In other embodiments (not separately illustrated), the integrated circuit dies are attached to the interposer 302 with direct bonds. For example, hybrid bonding, fusion bonding, dielectric bonding, metal bonding, or the like may be used to directly bond corresponding dielectric layers 58, 318 and/or die connectors 56, 316 of the integrated circuit dies 50 and the interposer 302 without the use of adhesive or solder. The underfill 334 may be omitted when direct bonding is used. Further, a mix of bonding techniques could be used, e.g., some integrated circuit dies 50 could be attached to the interposer 302 by solder bonds, and other integrated circuit dies 50 could be attached to the interposer 302 by direct bonds.

Still referring to FIG. 15, an encapsulant 336 is formed over the interposer 302 and on and around the integrated circuit dies 50. After formation, the encapsulant 336 encapsulates the integrated circuit dies 50, and the underfill 334 (if present) or the conductive connectors 332. The encapsulant 336 may be a molding compound, epoxy, or the like. The encapsulant 336 may be applied by compression molding, transfer molding, or the like, and is formed over the interposer 302 such that the integrated circuit dies 50 are buried or covered. The encapsulant 336 may be applied in liquid or semi-liquid form and then subsequently cured. The encapsulant 336 may be thinned to expose the integrated circuit dies 50. The thinning process may be a grinding process, a CMP, an etch-back, combinations thereof, or the like. After the thinning process, the top surfaces of the integrated circuit dies 50 and the encapsulant 336 are coplanar (within process variations) such that they are level with one another. The thinning is performed until a desired amount of the integrated circuit dies 50 and/or the encapsulant 336 has been removed.

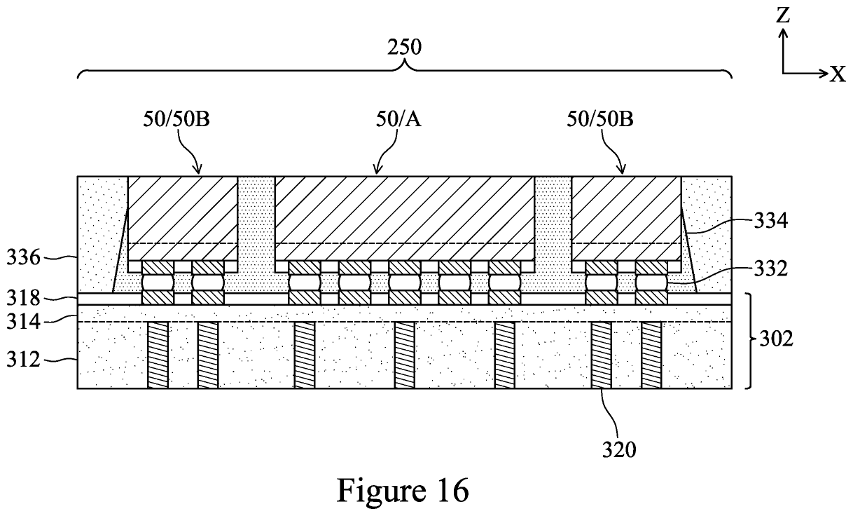

In FIG. 16, the substrate 312 is thinned to expose the conductive vias 320. Exposure of the conductive vias 320 may be accomplished by a thinning process, such as a grinding process, a chemical-mechanical polish (CMP), an etch-back, combinations thereof, or the like. In some embodiments (not separately illustrated), the thinning process for exposing the conductive vias 320 includes a CMP, and the conductive vias 320 protrude at the back-side of the interposer 302 as a result of dishing that occurs during the CMP. In such embodiments, an insulating layer (not separately illustrated) may optionally be formed on the back surface of the substrate 312, surrounding the protruding portions of the conductive vias 320. The insulating layer may be formed of a silicon-containing insulator, such as, silicon nitride, silicon oxide, silicon oxynitride, or the like, and may be formed by a suitable deposition method such as spin coating, CVD, plasma-enhanced CVD (PECVD), high density plasma CVD (HDP-CVD), or the like. After the substrate 312 is thinned, the exposed surfaces of the conductive vias 320 and the insulating layer (if present) or the substrate 312 are coplanar (within process variations) such that they are level with one another, and are exposed at the back-side of the interposer 302.

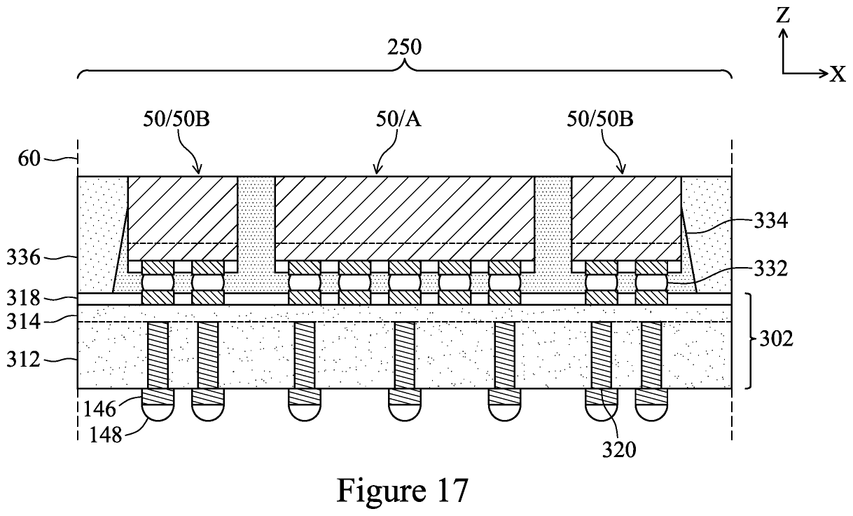

In FIG. 17, UBMs 146 are formed on the exposed surfaces of the conductive vias 320 and the substrate 312. As an example to form the UBMs 146 in this embodiment, a seed layer (not separately illustrated) is formed over the exposed surfaces of the conductive vias 320 and the substrate 312. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the UBMs 146. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the UBMs 146.

In addition, conductive connectors 148 are formed on the UBMs 146. The conductive connectors 148 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 148 may include a conductive material such as solder, copper, aluminum, gold, nickel, silver, palladium, tin, the like, or a combination thereof. In some embodiments, the conductive connectors 148 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 148 comprise metal pillars (such as copper pillars) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

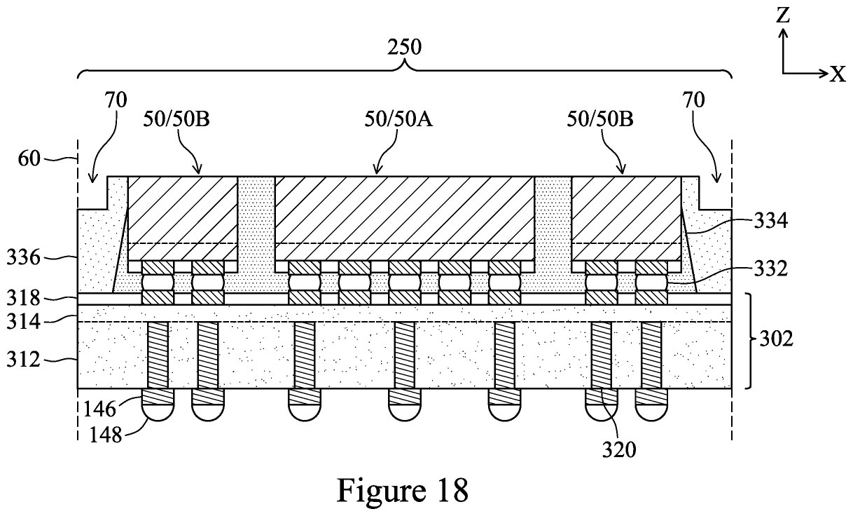

In FIGS. 18, the encapsulant 336 is laser etched along portions of the scribe regions 60 to form recesses 70 in the encapsulant 336. The laser etching may be performed similarly as described above in connection with FIGS. 7A-7F. In other embodiments, the laser etching may be performed after singulating the package component 250 and attaching the package component 250 to the package substrate 120, similarly as described above in connection with the integrated circuit package 200.

Further, a singulation process is performed by cutting along scribe regions e.g., around the package components 250. The singulation process may include sawing, dicing, or the like. For example, the singulation process can include sawing the encapsulant 336, the interposer 302 (e.g., the substrate 312), and the dielectric layer 318. The singulation process singulates the package components 250 from adjacent package components 250. As a result of the singulation process, the outer sidewalls of the interposer 302 and the encapsulant 336 are laterally coterminous (within process variations).

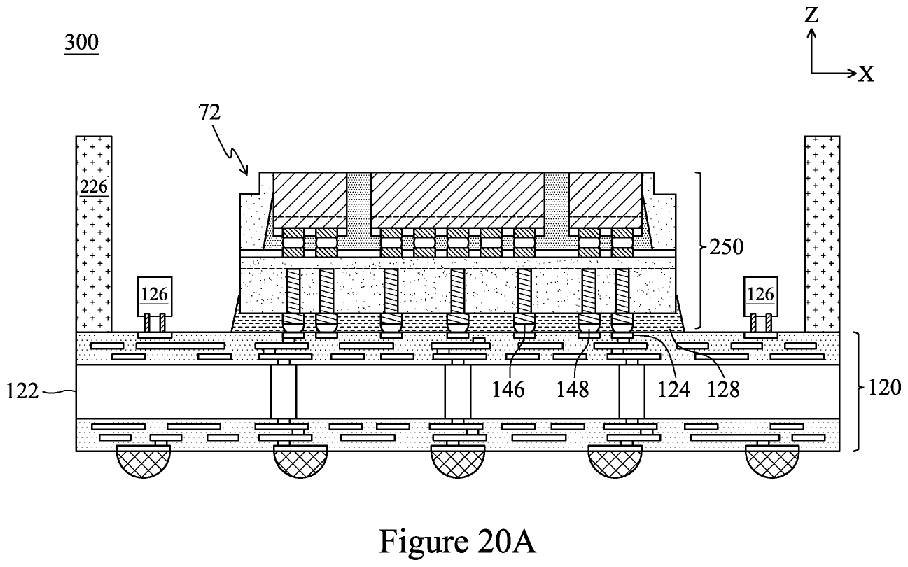

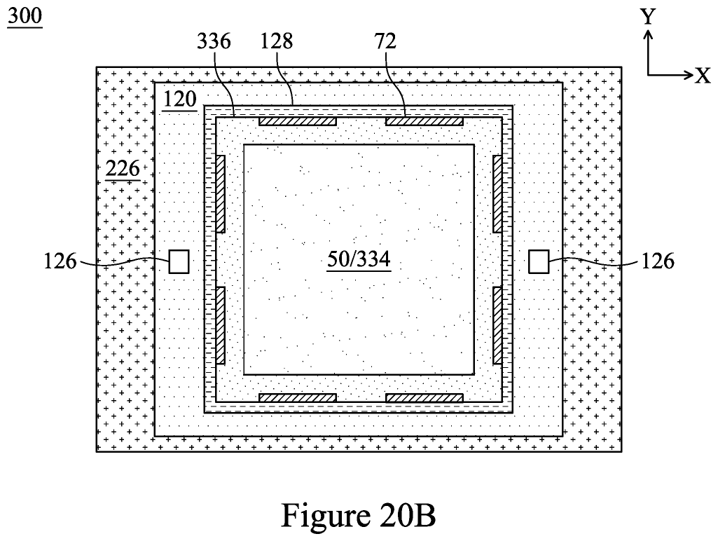

FIGS. 19A-20B illustrate various additional steps in the manufacturing of embodiment packages. For example, the package components 250 are attached to package substrates 120, and other devices, such as passive devices 126 and a ring assembly 226, may be attached to the package substrates 120, thus forming the integrated circuit packages 300. A single package component 250, a single package substrate 120, and a single integrated circuit package 300 are illustrated. It should be appreciated that multiple package components 250 can be simultaneously processed to form multiple integrated circuit packages 300.

In FIGS. 19A-19B, the package component 250 is attached to a package substrate 120 using the conductive connectors 148. In some embodiments, a singulation process is performed by cutting along the scribe regions 60, e.g., around the package component 250. In addition, the singulation process cuts through the recesses 70 to form the recessed regions 72 along the outer edges of the encapsulant 336 of the package component 250. The singulation process may include sawing, dicing, or the like. For example, the singulation process can include sawing the encapsulant 336, the interposer 302 (e.g., the substrate 312 and the interconnect structure 314), and the dielectric layer 318. The singulation process singulates the package component 250 from adjacent package components 250. As a result of the singulation process, the outer sidewalls of the interposer 302 and the encapsulant 336 are laterally coterminous (within process variations).

Similarly as described above in connection with the package component 150 and the integrated circuit package 100, upon singulation of the package component 250, the recesses 70 become the recessed regions 72 along the outer edges of the encapsulant 336. As illustrated, each corner region of the encapsulant 336 may correspond to two outer edges, which each contain the recessed regions 72. As discussed above in connection with the integrated circuit package 100, any number of the recessed regions 72 may be formed along the outer edges of the encapsulant 336. For example, profiles and patterns of the recessed regions 72 may be selected similarly as described above in connection with the integrated circuit package 100 (see, e.g., FIGS. 8A-8F and 10A-10D).

The package substrate 120 may include a substrate core 122 and is as described above in connection with the integrated circuit packages 100 and 200. In addition, the singulated package component 250 may be attached to the package substrate 120 similarly as described above in connection with the integrated circuit packages 100 and 200.

In FIGS. 20A-20B, passive devices 126 may be attached to the package substrate 120. In addition, a ring assembly 226 may be attached to the package substrate 120 and around the package component 250 and the passive devices 126 (if present). In some embodiments, the passive devices 126 (e.g., SMDs) may be attached to the bond pads 124 of the package substrate 120. In some embodiments (not specifically illustrated), the passive devices 126 may be attached to the package substrate 120 before attaching the package component 250 to the package substrate 120. The ring assembly 226 may be formed and/or attached to the package substrate 120 similarly as described above in connection with the integrated circuit packages 100, 200.

Embodiments may achieve advantages. The recessed regions 72 formed in the encapsulant 336 reduce the generation of stress in the encapsulant, for example, as a result of thermal processes during the assembly and testing of the integrated circuit packages 100, 200, 300. In addition, selection of dimensions and patterns of the recessed regions 72 may allow for focused control of stress mitigation in specific portions of the encapsulant 336 at elevated risk of stress and cracking.

In an embodiment, a method of forming a semiconductor device includes: attaching an integrated circuit die to an interposer; forming an encapsulant over the interposer and around the integrated circuit die, a top surface of the encapsulant and a top surface of the integrated circuit die being level; forming recesses in the encapsulant; and bonding the interposer to a package substrate, wherein after bonding the interposer to the package substrate, each of the recesses being along an outer edge of the encapsulant. In another embodiment, the method further includes, after forming the recesses, singulating the interposer from a wafer, wherein the singulating is performed through the recesses. In another embodiment, forming the recesses is performed after bonding the interposer to the package substrate, and wherein forming the recesses comprises forming the recesses along the outer edge of the encapsulant. In another embodiment, the recesses have profiles with a rectangular shape in a cross-sectional view. In another embodiment, the recesses have profiles with a V-shape in a cross-sectional view. In another embodiment, the recesses have profiles with a U-shape in a cross-sectional view. In another embodiment, the encapsulant comprises four outer edges, and wherein each of the outer edges of the encapsulant comprises more than two recesses. In another embodiment, the encapsulant has a thickness around an outer sidewall of the integrated circuit die, and wherein a distance of one of the recesses from a corresponding corner of the encapsulant is less than the thickness.

In an embodiment, a semiconductor device includes: a package substrate; an interposer disposed over the package substrate; conductive connectors electrically connecting the interposer to the package substrate; an integrated circuit die disposed over and electrically connected to the interposer, the integrated circuit die comprising a first sidewall and a second sidewall, in a top-down view the first sidewall and the second sidewall converging at a corner of the integrated circuit die; and an encapsulant along the first sidewall and the second sidewall of the integrated circuit die, the encapsulant comprising: a first recess parallel to the first sidewall; and a second recess parallel to the second sidewall, the first sidewall being perpendicular to the second sidewall. In another embodiment, the semiconductor device further includes: a third recess on the first sidewall, wherein in the top-down view the first recess and the third recess share a first longitudinal axis; and a fourth recess on the second sidewall, wherein in the top-down view the second recess and the fourth recess share a second longitudinal axis. In another embodiment, a first length of the first recess is less than a third length of the third recess, and wherein a second length of the second recess is less than a fourth length of the fourth recess. In another embodiment, each of the first recess, the second recess, the third recess, and the fourth recess has a same length. In another embodiment, a top surface of the encapsulant is level with a top surface of the integrated circuit die, wherein the first recess forms a first bevel along a first outer edge of the encapsulant, and wherein the second recess forms a second bevel along a second outer edge of the encapsulant. In another embodiment, in the top-down view the first recess and the second recess have a same length. In another embodiment, in the top-down view the corner of the integrated circuit die is more proximal to the first outer edge of the encapsulant than the second recess is to the first outer edge of the encapsulant, and wherein in the top-down view the corner of the integrated circuit die is more proximal to the second outer edge of the encapsulant than the first recess is to the second outer edge of the encapsulant. In another embodiment, in the top-down view the corner of the integrated circuit die is more distal from the first outer edge of the encapsulant than the second recess is from the first outer edge of the encapsulant, and wherein in the top-down view the corner of the integrated circuit die is more distal from the second outer edge of the encapsulant than the first recess is from the second outer edge of the encapsulant.

In an embodiment, a semiconductor device includes: an interposer; an integrated circuit die attached to the interposer; and an encapsulant disposed laterally around a perimeter of the integrated circuit die, the encapsulant comprising a first portion along a first sidewall of the integrated circuit die and a second portion along a second sidewall of the integrated circuit die, wherein the first sidewall and the second sidewall meet at a corner of the integrated circuit die, the encapsulant further comprising a first recessed region along an outer edge of the first portion of the encapsulant. In another embodiment, the encapsulant further comprises a second recessed region along the second portion of the encapsulant, wherein there are more recessed regions in the first portion than in the second portion. In another embodiment, the first recessed region forms a bevel along the first portion of the encapsulant. In another embodiment, the bevel is concave.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
attaching an integrated circuit die to an interposer;
forming an encapsulant over the interposer and around the integrated circuit die, a top surface of the encapsulant and a top surface of the integrated circuit die being level;
forming recesses in the encapsulant; and
bonding the interposer to a package substrate, wherein after bonding the interposer to the package substrate, each of the recesses being along an outer edge of the encapsulant.

2. The method of claim 1, further comprising, after forming the recesses, singulating the interposer from a wafer, wherein the singulating is performed through the recesses.

3. The method of claim 1, wherein forming the recesses is performed after bonding the interposer to the package substrate, and wherein forming the recesses comprises forming the recesses along the outer edge of the encapsulant.

4. The method of claim 1, wherein the recesses have profiles with a rectangular shape in a cross-sectional view.

5. The method of claim 1, wherein the recesses have profiles with a V-shape in a cross-sectional view.

6. The method of claim 1, wherein the recesses have profiles with a U-shape in a cross-sectional view.

7. The method of claim 1, wherein the encapsulant comprises four outer edges, and wherein each of the outer edges of the encapsulant comprises more than two recesses.

8. The method of claim 1, wherein the encapsulant has a thickness around an outer sidewall of the integrated circuit die, and wherein a distance of one of the recesses from a corresponding corner of the encapsulant is less than the thickness.

9. A semiconductor device comprising:
a package substrate;
an interposer disposed over the package substrate;
conductive connectors electrically connecting the interposer to the package substrate;
an integrated circuit die disposed over and electrically connected to the interposer, the integrated circuit die comprising a first sidewall and a second sidewall, in a top-down view the first sidewall and the second sidewall converging at a corner of the integrated circuit die; and
an encapsulant along the first sidewall and the second sidewall of the integrated circuit die, the encapsulant comprising:
a first recess parallel to the first sidewall; and
a second recess parallel to the second sidewall, the first sidewall being perpendicular to the second sidewall.

10. The semiconductor device of claim 9, further comprising:
a third recess on the first sidewall, wherein in the top-down view the first recess and the third recess share a first longitudinal axis; and
a fourth recess on the second sidewall, wherein in the top-down view the second recess and the fourth recess share a second longitudinal axis.

11. The semiconductor device of claim 10, wherein a first length of the first recess is less than a third length of the third recess, and wherein a second length of the second recess is less than a fourth length of the fourth recess.

12. The semiconductor device of claim 10, wherein each of the first recess, the second recess, the third recess, and the fourth recess has a same length.

13. The semiconductor device of claim 9, wherein a top surface of the encapsulant is level with a top surface of the integrated circuit die, wherein the first recess forms a first bevel along a first outer edge of the encapsulant, and wherein the second recess forms a second bevel along a second outer edge of the encapsulant.

14. The semiconductor device of claim 13, wherein in the top-down view the first recess and the second recess have a same length.

15. The semiconductor device of claim 14, wherein in the top-down view the corner of the integrated circuit die is more proximal to the first outer edge of the encapsulant than the second recess is to the first outer edge of the encapsulant, and wherein in the top-down view the corner of the integrated circuit die is more proximal to the second outer edge of the encapsulant than the first recess is to the second outer edge of the encapsulant.

16. The semiconductor device of claim 14, wherein in the top-down view the corner of the integrated circuit die is more distal from the first outer edge of the encapsulant than the second recess is from the first outer edge of the encapsulant, and wherein in the top-down view the corner of the integrated circuit die is more distal from the second outer edge of the encapsulant than the first recess is from the second outer edge of the encapsulant.

17. A semiconductor device comprising:
an interposer;
an integrated circuit die attached to the interposer; and
an encapsulant disposed laterally around a perimeter of the integrated circuit die, the encapsulant comprising a first portion along a first sidewall of the integrated circuit die and a second portion along a second sidewall of the integrated circuit die, wherein the first sidewall and the second sidewall meet at a corner of the integrated circuit die, the encapsulant further comprising a first recessed region along an outer edge of the first portion of the encapsulant.

18. The semiconductor device of claim 17, wherein the encapsulant further comprises a second recessed region along the second portion of the encapsulant, wherein there are more recessed regions in the first portion than in the second portion.

19. The semiconductor device of claim 17, wherein the first recessed region forms a bevel along the first portion of the encapsulant.

20. The semiconductor device of claim 19, wherein the bevel is concave.
